(19) United States
(12) Patent Application Publication
(10) Pub. No.: US 2023/0358536 A1
(43) Pub. Date: Nov. 9, 2023

(54) Method for Determining a Position and/or Orientation of a Measuring Device

(71) Applicant: Hilti Aktiengesellschaft, Schaan (LI)

(72) Inventors: Thomas GLOOR, Triesen (LI); Clemens ARTH, Gratwein-Strassengel (AT); Mehdi STAPLETON, Graz (AT)

(21) Appl. No.: 17/802,726

(22) PCT Filed: Feb. 15, 2021
(86) PCT No.: PCT/EP2021/053630

§ 371 Date: Aug. 26, 2022

(30) Foreign Application Priority Data
Feb. 27, 2020 (EP) 20159822.4

(51) Int. Cl. G01C 15/00; G06N 3/08

(52) U.S. Cl. CPC G01C 15/004; G06N 3/08

(57) ABSTRACT

A method for determining a position and/or orientation of a measuring device in a measuring environment which is mapped in a geometry model by a trained artificial neural network that has been trained by known measuring environments to give a prognosis of the need for a further measurement by the measuring device and, if necessary, a prognosis of the suitability of a measuring position of the measuring device.

### BACKGROUND AND SUMMARY OF THE INVENTION

The present invention relates to a method for determining a position and/or orientation of a measuring device, a method for precisely specifying the position and/or orientation of a measuring device, an apparatus for determining a position and/or orientation of a measuring device, and a computer program product.

Measuring devices, such as for example total stations, have angle and distance measuring devices and take angle and distance measurements in relation to selected target objects. The angle and distance measured values are measured in the reference system of the measuring device and must still be linked to an external reference system for an absolute determination of the position.

In known methods for determining a position and/or orientation of a measuring device in an external reference system, target objects are positioned at known control points and the coordinates of the control points are measured in the reference system of the measuring device; the coordinates of the control points in the external reference system are known. The position and/or orientation of the measuring device is determined by means of the coordinates of the control points in the external reference system and in the reference system of the measuring device. The disadvantage is that the control points must be provided and measured in the measuring environment; measuring the control points requires an experienced operator and is susceptible to errors.

The object of the present invention is to develop a method for determining a position and/or orientation of a measuring device in which the susceptibility to errors is reduced. In addition, if possible, the accuracy with which the position and/or orientation of the measuring device is determined should be improved and/or the time required for this should be reduced.

The method according to the invention for determining a position and/or orientation of a measuring device in a measuring environment, which is mapped in a geometry model, has the following steps:
providing a trained artificial neural network that has been trained by means of known measuring environments to give a prognosis of the need for a further measurement by the measuring device and, if necessary, of the suitability of a measuring position of the measuring device,
defining a group of actions comprising at least a “Cancel” action, an “Adjust 1” action and a “Measure 1” action, where the “Cancel” action means that no further measurement by the measuring device is required, the “Adjust 1” action means that a further measurement by the measuring device is required and the current measuring position of the measuring device is assessed as unsuitable, and the “Measure 1” action means that a further measurement by the measuring device is required and the current measuring position of the measuring device is assessed as suitable,
initializing a probability grid for the position and/or orientation of the measuring device in the measuring environment,
performing a sequence of steps, where
(1) in a first step of the sequence, the need for a further measurement by the measuring device and the suitability of the current measuring position of the measuring device is assessed by using the trained artificial neural network, the assessment being carried out in the form of a degree of fulfillment for the actions of the group of actions,
(2) in a second step of the sequence, the action for which the best degree of fulfillment was determined in the first step is determined as the best action,
(3) in a third step of the sequence, it is checked whether the best action coincides with the “Cancel” action, where
in the event that the best action does not coincide with the “Cancel” action, the sequence of steps is continued, and
in the event that the best action coincides with the “Cancel” action, the sequence of steps is canceled,
(4) in a fourth step of the sequence, the best action is executed, where
in the event that the “Adjust 1” action was determined as the best action, the measuring device is arranged in a new measuring position and the method is continued with the first step of the sequence, and
in the event that the “Measure 1” action was determined as the best action, a measurement is carried out by means of the measuring device in the current measuring position, the probability grid for the position and/or orientation of the measuring device in the measuring environment is updated and the method is continued with the first step of the sequence,
continuing the method after the sequence has been canceled in the third step with the calculation of the position and/or orientation of the measuring device in the measuring environment.

The concept of the present invention is to determine the position and/or orientation of a measuring device in the measuring environment by means of a trained artificial neural network. The artificial neural network is trained in advance by means of known measuring environments so that a prognosis of the need for a further measurement by the measuring device and of the suitability of a measuring position of the measuring device can be given. Each measuring environment that is used for training the artificial neural network is defined by a geometry model and is mapped in several images. The use of the trained artificial neural network makes it possible to assess the quality of measuring points of the measuring environment in order to achieve a high degree of accuracy for the position and/or orientation of the measuring device in the reference system of the measuring environment with a reduced number of measurements by the measuring device. The method according to the invention makes it possible to select suitable measuring positions, that is to say measuring positions of which the associated measured values reduce the inaccuracy when determining the position and/or orientation of the measuring device. The main advantage for the user is that no control points have to be provided in the measuring environment and there is no need to measure the control points. The measuring device can be used in any measuring environment that is mapped in a geometry model. A construction model of the measuring environment produced with CAD support can be used for example as the geometry model, or the measuring environment is scanned by means of a laser scanner and a geometry model of the measuring environment is created from the scan data.

The actions that the measuring device can execute during the method according to the invention are defined in a group of actions comprising at least a “Cancel” action, an “Adjust 1” action and a “Measure 1” action. The “Cancel” action means that no further measurement by the measuring device is required; the measured values determined by the measuring device are sufficient to determine the position and/or orientation of the measuring device with the required accuracy. The “Adjust 1” action means that a further measurement by the measuring device is required and the current measuring position of the measuring device is assessed as unsuitable, a measuring position being assessed as unsuitable if the inaccuracy in determining the position and/or orientation of the measuring device is not reduced. The “Measure 1” action means that a further measurement by the measuring device is required and the current measuring position of the measuring device is assessed as suitable, a measuring position being assessed as suitable if the inaccuracy in determining the position and/or orientation of the measuring device is reduced.

At the beginning of the method according to the invention, a probability grid for the position and/or orientation of the measuring device in the measuring environment is initialized, the probability being evenly distributed, i.e., all positions and/or orientations in the measuring environment have the same probability. The probability grid for the position and/or orientation of the measuring device in the measuring environment is updated during the method according to the invention by means of measured values determined by the measuring device.

The method according to the invention comprises a sequence of four steps, which are performed repeatedly until the sequence is canceled. In a first step of the sequence, the need for a further measurement by the measuring device and the suitability of the current measuring position of the measuring device is assessed by using the trained artificial neural network, the assessment being carried out in the form of a degree of fulfillment for the actions of the group of actions. In a second step of the sequence, the action for which the best degree of fulfillment was determined in the first step is determined as the best action, and in a third step of the sequence it is checked whether the best action coincides with the “Cancel” action. The further sequence depends on the result of the check in the third step. In the event that the best action coincides with the “Cancel” action, the sequence of steps is canceled and the method according to the invention is continued and ended with the calculation of the position and/or orientation of the measuring device in the measuring environment. In the event that the best action does not coincide with the “Cancel” action, the sequence of steps is continued with a fourth step. In the fourth step of the sequence, the best action is executed, where, in the event that the “Adjust 1” action was determined as the best action, the measuring device is arranged in a new predetermined measuring position and the method is continued with the first step of the sequence. In the event that the “Measure 1” action was determined as the best action, a measurement is carried out by means of the measuring device in the current measuring position, the probability grid for the position and/or orientation of the measuring device is updated in the measuring environment and the method is continued with the first step of the sequence.

The position and/or orientation of the measuring device in the measuring environment is preferably calculated from the probability grid. If the “Cancel” action is determined as the best action when the method according to the invention is performed, no further measurement by the measuring device is required; the measured values determined by the measuring device are sufficient to determine the position and/or orientation of the measuring device with the required accuracy. The position and/or orientation of the measuring device in the measuring environment is in this case calculated from the probability grid.

The artificial neural network was preferably trained to assess the current measuring position of the measuring device as suitable if the inaccuracy in determining the position and/or orientation of the measuring device is reduced. This training means that the measuring device only takes a measurement if the measuring position is suitable. Since the “Measure 1” action takes more time than the “Adjust 1” action, the time required to determine the position and/or orientation of the measuring device is reduced.

The artificial neural network was preferably trained to deny the need for a further measurement by the measuring device if the inaccuracy in determining the position and/or orientation of the measuring device falls below a predetermined value. This training results in the measurement with the measuring device being ended as part of the method according to the invention when the required accuracy for the position and/or orientation of the measuring device in the measuring environment has been achieved.

When executing the “Adjust 1” action, at least one image of the measuring environment is preferably recorded in the current measuring position and/or the new predetermined measuring position by means of a camera device. The images of the measuring environment are saved and taken into account when updating the probability grid.

In a preferred further development of the method, the group of actions comprises, in addition to the “Cancel” action, “Adjust 1” action and “Measure 1” action, an “Adjust 2” action, which is different from the “Adjust 1” action, and/or a “Measure 2” action, which is different from the “Measure 1” action. For all of the actions of the group of actions, when the method according to the invention is performed, a degree of fulfillment is calculated in the first step of the sequence and the action for which the best degree of fulfillment was determined is determined as the best action and executed.

Particularly preferably, the “Adjust 2” action differs from the “Adjust 1” action by an adjustment direction and/or an adjustment angle. A degree of fulfillment is calculated for the “Adjust 1” and “Adjust 2” actions when the method according to the invention is performed.

Particularly preferably, the “Measure 2” action differs from the “Measure 1” action by a measuring time and/or a measuring accuracy. A degree of fulfillment is calculated for the “Measure 1” and “Measure 2” actions when the method according to the invention is performed.

The present invention also relates to a method for precisely specifying a position and/or orientation of a measuring device, the position and/or orientation of the measuring device having been determined by means of the method herein. The position and/or orientation of the measuring device in the measuring environment is determined by means of the method according to the invention, while this position and/or orientation can then be specified more precisely by means of known methods.

The present invention also relates to an apparatus for determining a position and/or orientation of a measuring device by means of the method for determining a position and/or orientation disclosed herein. In addition to the measuring device, the apparatus comprises a control device which is connected to the measuring device via a communication link.

The present invention also relates to a computer program product, comprising a sequence of control commands stored thereon which, when executed by a control device, causes a measuring device to carry out the method disclosed herein. The method according to the invention is performed by the control device, which is connected to the measuring device via a communication link.

Exemplary embodiments of the invention are described hereinafter with reference to the drawings. It is not necessarily intended for this to illustrate the exemplary embodiments to scale; rather, the drawings are produced in a schematic and/or slightly distorted form where this is useful for purposes of explanation. It should be taken into account here that various modifications and alterations relating to the form and detail of an embodiment may be undertaken without departing from the general concept of the invention. The general concept of the invention is not limited to the exact form or the detail of the preferred embodiment shown and described hereinafter or limited to subject matter that would be restricted compared to the subject matter claimed in the claims. For given dimensioning ranges, values within the stated limits should also be disclosed as limit values and should be able to be used and claimed as desired. For the sake of simplicity, the same reference signs are used hereinafter for identical or similar parts or parts having an identical or similar function.

### BRIEF DESCRIPTION OF THE DRAWINGS

FIG. 1 shows an apparatus with a measuring device, the position and/or orientation of which is to be determined in a measuring environment by means of a method according to the invention;

FIG. 2 shows the method according to the invention for determining the position and/or orientation of the measuring device of FIG. 1 in a measuring environment in the form of a flow diagram;

FIG. 3 shows a probability grid for three different orientations at the beginning of the method according to the invention;

FIG. 4 shows a probability grid for three different orientations during the performance of the method according to the invention; and

FIG. 5 shows a probability grid for three different orientations at the end of the method according to the invention.

### DETAILED DESCRIPTION OF THE DRAWINGS

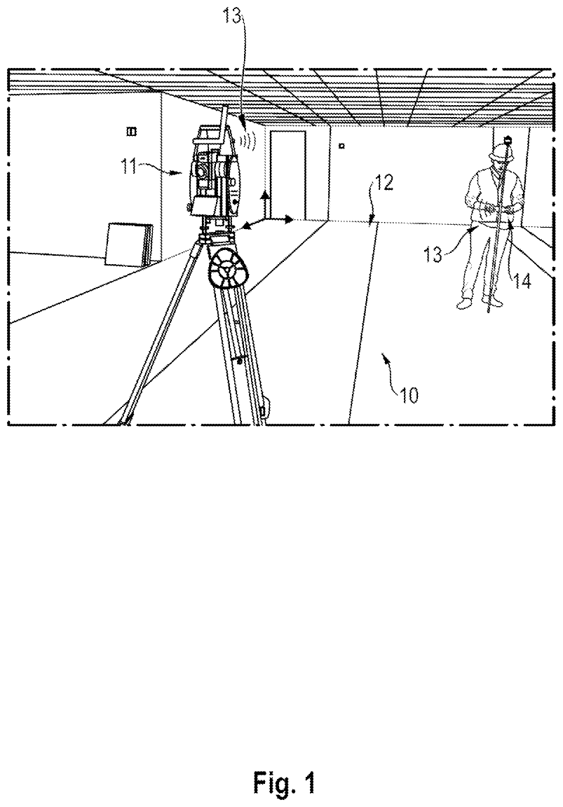

FIG. 1 shows an apparatus 10 with a measuring device 11, the position and/or orientation of which is to be determined in a measuring environment 12 by means of a method according to the invention. “Measuring device” is a collective term for all devices intended for carrying out measurement tasks. The measuring device 11, which in the exemplary embodiment is designed as a total station, is connected to a control device 14 via a communication link 13. The method according to the invention is controlled by way of the control device 14.

The measuring environment 12 is mapped in a geometry model. A construction model of the measuring environment 12 produced with CAD support can be used as the geometry model. Alternatively, the measuring environment 12 may be scanned by means of a laser scanner and a geometry model of the measuring environment 12 created from the scan data. The geometry model may map the measuring environment 12 completely or only partially. The surfaces of the measuring environment 12 that are used as a reflection surface or scatter surface for a distance measurement are decisive for the present application.

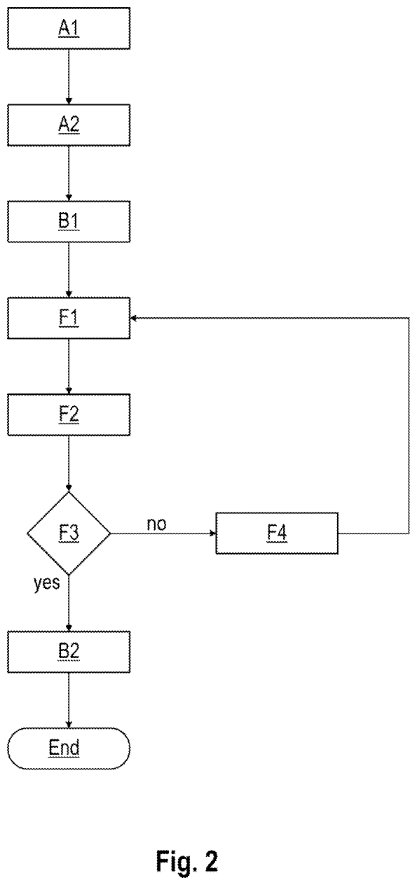

FIG. 2 shows the method according to the invention for determining the position and/or orientation of the measuring device 10 of FIG. 1 in a measuring environment in the form of a flow diagram. The method is described on the basis of the apparatus 10 shown in FIG. 1 with the measuring device 11 and the control device 13.

The concept of the method according to the invention is to determine the position and/or orientation of the measuring device 11 in the measuring environment 12 by means of a trained artificial neural network. For this purpose, in a step A1, an artificial neural network is trained by means of known measuring environments so that a prognosis of the need for a further measurement by the measuring device 11 and of the suitability of a measuring position of the measuring device 11 can be given. Each measuring environment that is used for training the artificial neural network is defined by a geometry model and is mapped in several images.

The actions that the measuring device 11 can execute during the method according to the invention are defined in a step A2 in a group of actions comprising at least a “Cancel” action, an “Adjust 1” action and a “Measure 1” action. The “Cancel” action means that no further measurement by the measuring device 11 is required and the measured values determined by the measuring device 11 are sufficient to determine the position and/or orientation of the measuring device 11 in the measuring environment 12 with the required accuracy. The “Adjust 1” action means that a further measurement by the measuring device 11 is required and the current measuring position of the measuring device 11 is assessed as unsuitable, and the “Measure 1” action means that a further measurement by the measuring device 11 is required and the current measuring position of the measuring device 11 is assessed as suitable. A measuring position is assessed as suitable if the inaccuracy in determining the position and/or orientation of the measuring device 11 is reduced.

The method according to the invention comprises a sequence of steps F1, F2, F3 and F4, which are performed repeatedly until the sequence is canceled. In the first step F1 of the sequence, the need for a further measurement by the measuring device 11 and the suitability of the current measuring position of the measuring device 11 is assessed by using the trained artificial neural network, the assessment being carried out in the form of a degree of fulfillment for the actions of the group of actions. In the second step F2 of the sequence, the action for which the best degree of fulfillment was determined in the first step is determined as the best action, and in the third step F3 of the sequence it is checked whether the best action coincides with the “Cancel” action.

The further course of the method according to the invention depends on the result of the check in the third step F3. In the event that the best action coincides with the “Cancel” action (yes in step F3), the sequence of steps is canceled and the method according to the invention is continued with the calculation of the position and/or orientation of the measuring device 11 in the measuring environment 12 in a step B2 and ended after step B2. In the event that the best action does not coincide with the “Cancel” action (no in step F3), the sequence of steps is continued with the fourth step F4. In the fourth step F4 of the sequence, the best action is executed, where, in the event that the “Adjust 1” action was determined as the best action, the measuring device 11 is arranged in a new predetermined measuring position and the method according to the invention is continued with the first step F1 of the sequence. In the event that the “Measure 1” action was determined as the best action, a measurement is carried out by means of the measuring device 11 in the current measuring position, the probability grid for the position and/or orientation of the measuring device 11 in the measuring environment is updated and the method is continued with the first step F1 of the sequence.

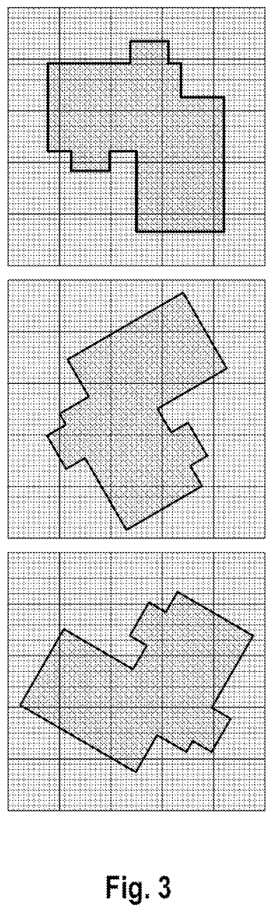

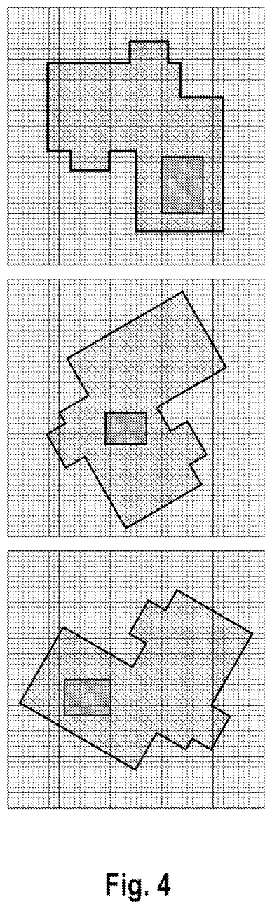

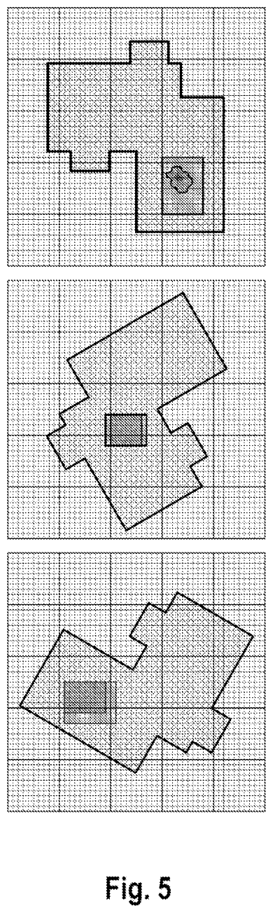

As part of the method according to the invention, the position and/or orientation of the measuring device 11 in the measuring environment 12 is calculated from a probability grid. The probability distribution is mapped in the probability grid for the measuring environment 12 in which the position and/or orientation of the measuring device 12 is to be determined. FIG. 3 shows the probability grid for three different orientations at the beginning of the method according to the invention, FIG. 4 shows the probability grid for three different orientations during the performance of the method according to the invention and FIG. 5 shows the probability grid for three different orientations at the end of the method according to the invention.

At the beginning of the method according to the invention, the probability grid for the position and/or orientation of the measuring device 11 in the measuring environment 12 is initialized, the probability being evenly distributed, i.e., all positions and orientations in the measuring environment have the same probability (FIG. 3). During the performance of the method according to the invention, the sequence of steps F1, F2, F3 and F4 is performed repeatedly; the measured values determined in the fourth step are used to update the probability grid (FIG. 4). The sequence of steps F1, F2, F3 and F4 is canceled if the best action coincides with the “Cancel” action in the third step F3, and the method according to the invention is ended with the calculation of the position and/or orientation of the measuring device 11 in the measuring environment 12; the position and/or orientation of the measuring device 11 is determined from the probability grid (FIG. 5).

1.-11. (canceled)

12. A method for determining a position and/or orientation of a measuring device (11) in a measuring environment (12) which is mapped in a geometry model, comprising the steps of:
providing a trained artificial neural network that has been trained by known measuring environments to give a prognosis of a need for a further measurement by the measuring device (11) and, if necessary, a prognosis of a suitability of a measuring position of the measuring device (11);
defining a group of actions comprising at least a “Cancel” action, an “Adjust 1” action and a “Measure 1” action, wherein the “Cancel” action means that no further measurement by the measuring device (11) is required, the “Adjust 1” action means that a further measurement by the measuring device (11) is required and a current measuring position of the measuring device (11) is assessed as unsuitable, and the “Measure 1” action means that a further measurement by the measuring device (11) is required and a current measuring position of the measuring device (11) is assessed as suitable,
initializing a probability grid for the position and/or orientation of the measuring device (11) in the measuring environment (12);
performing a sequence of steps, wherein:
(1) in a first step of the sequence, a need for a further measurement by the measuring device (11) and a suitability of the current measuring position of the measuring device (11) is assessed by using the trained artificial neural network, the assessment being carried out in a form of a degree of fulfillment for the actions of the group of actions;
(2) in a second step of the sequence, the action for which a best degree of fulfillment was determined in the first step is determined as a best action;
(3) in a third step of the sequence, checking whether the best action coincides with the “Cancel” action, wherein:
in an event that the best action does not coincide with the “Cancel” action, the sequence of steps is continued; and
in an event that the best action coincides with the “Cancel” action, the sequence of steps is cancelled;
(4) in a fourth step of the sequence, the best action is executed, wherein:
in an event that the “Adjust 1” action was determined as the best action, the measuring device (11) is arranged in a new measuring position and the method is continued with the first step of the sequence; and
in an event that the “Measure 1” action was determined as the best action, a measurement is carried out by the measuring device (11) in the current measuring position, the probability grid for the position and/or orientation of the measuring device (11) in the measuring environment (12) is updated and the method is continued with the first step of the sequence;
continuing the method after the sequence has been cancelled in the third step with a calculation of the position and/or orientation of the measuring device (11) in the measuring environment (12).

13. The method as claimed in claim 12, wherein the position and/or orientation of the measuring device (11) in the measuring environment (12) is calculated from the probability grid.

14. The method as claimed in claim 12, wherein the trained artificial neural network has been trained to assess the current measuring position of the measuring device (11) as suitable if an inaccuracy in determining the position and/or orientation of the measuring device (11) is reduced.

15. The method as claimed in claim 12, wherein the trained artificial neural network has been trained to deny the need for a further measurement by the measuring device (11) if an inaccuracy in determining the position and/or orientation of the measuring device (11) falls below a specified value.

16. The method as claimed in claim 12, wherein, when executing the “Adjust 1” action, at least one image of the measuring environment (12) is recorded in an old measuring position and/or the new measuring position by a camera device.

17. The method as claimed in claim 12, wherein the group of actions comprises, in addition to the “Cancel” action, the “Adjust 1” action and the “Measure 1” action, an “Adjust 2” action which is different from the “Adjust 1” action and/or a “Measure 2” action which is different from the “Measure 1” action.

18. The method as claimed in claim 17, wherein the “Adjust 2” action differs from the “Adjust 1” action by an adjustment direction and/or an adjustment angle.

19. The method as claimed in claim 17, wherein the “Measure 2” action differs from the “Measure 1” action by a measuring time and/or a measuring accuracy.

20. A method for precisely specifying a position and/or orientation of a measuring device (11), wherein the position and/or orientation of the measuring device has been determined by the method for determining the position and/or orientation as claimed in claim 12.

21. An apparatus (10) for determining a position and/or orientation of a measuring device (11) in a measuring environment (12) by the method for determining the position and/or orientation as claimed in claim 12.

22. A computer program product, comprising a sequence of control commands stored on the computer program product which, when executed by a control device (14), causes a measuring device (11) to carry out the method for determining the position and/or orientation as claimed in claim 12.
